(19) United States
(12) Patent Application Publication
(10) Pub. No.: US 2025/0095954 A1
(43) Pub. Date: Mar. 20, 2025

(54) High-Frequency Power Supply, Plasma Processing Device, and Matching Method

(71) Applicant: Tokyo Electron Limited, Tokyo (JP)

(72) Inventors: Taro IKEDA, Yamanashi (JP); Hiroyuki MIYASHITA, Yamanashi (JP); Yuki OSADA, Yamanashi (JP)

(21) Appl. No.: 18/967,559

(22) Filed: Dec. 3, 2024

Related U.S. Application Data
(63) Continuation of application No. PCT/JP2023/021398, filed on Jun. 8, 2023.

(30) Foreign Application Priority Data
Jun. 16, 2022 (JP) 2022-097170

(51) Int. Cl. H01J 37/24; H01J 37/32

(52) U.S. Cl. CPC H01J 37/24; H01J 37/32229; H01J 37/32247

(57) ABSTRACT

Provided is a high-frequency power supply comprising: a power generator configured to generate a high-frequency power having a variable frequency; an output part configured to output the high-frequency power; a sensor configured to specify a reflection coefficient of the high-frequency power for a load connected to the output part; and a controller configured to determine a matching frequency of the high-frequency power for the load, wherein the controller is configured to: (i) obtain three reflection coefficients corresponding to a first frequency, a second frequency, and a third frequency from the sensor; (ii) determine, as the matching frequency, a frequency of a minimum point of a quadratic function that expresses the relationship between the first to third frequencies and the three reflection coefficients; and (iii) control the power generator to generate the high-frequency power having the matching frequency.

### CROSS-REFERENCE TO RELATED APPLICATIONS

This application is a bypass continuation application of International Application No. PCT/JP2023/021398 having an international filing date of Jun. 8, 2023 and designating the United States, the International Application being based upon and claiming the benefit of priority from the Japanese Patent Application No. 2022-097170 filed on Jun. 16, 2022, the entire contents of which are incorporated herein by reference.

### TECHNICAL FIELD

Exemplary embodiments of the present disclosure relate to a high-frequency power supply, a plasma processing apparatus, and a matching method.

### BACKGROUND

A plasma processing apparatus is used for manufacturing devices. In Japanese Laid-open Patent Publication No. 2018-88323, microwaves are used for producing plasma, and an absorption frequency at which a reflection coefficient becomes minimum is specified by sweeping a frequency of the microwaves within a bandwidth.

### SUMMARY

The present disclosure provides a technique for quickly determining a matching frequency of a high-frequency power used for producing plasma.

In accordance with an aspect of the present disclosure, there is provided a high-frequency power supply comprising: a power generator configured to generate a high-frequency power having a variable frequency; an output part configured to output the high-frequency power; a sensor configured to specify a reflection coefficient of the high-frequency power for a load connected to the output part; and a controller configured to determine a matching frequency of the high-frequency power for the load, wherein the controller is configured to: (i) obtain three reflection coefficients corresponding to a first frequency, a second frequency, and a third frequency from the sensor by using the first frequency, the second frequency, and the third frequency that are different from each other as frequencies of the high-frequency power; (ii) determine, as the matching frequency, a frequency of a minimum point of a quadratic function that expresses the relationship between the first to third frequencies and the three reflection coefficients; and (iii) control the power generator to generate the high-frequency power having the matching frequency.

### BRIEF DESCRIPTION OF THE DRAWINGS

FIG. 1 is a cross-sectional view schematically showing a plasma processing apparatus according to one embodiment.

FIG. 2 is a partially enlarged cross-sectional view of a waveguide of a plasma processing apparatus according to one embodiment.

FIG. 3 schematically shows a high-frequency power supply according to one exemplary embodiment.

FIG. 4 is a flowchart of a matching method according to one exemplary embodiment.

### DETAILED DESCRIPTION

Hereinafter, various exemplary embodiments will be described in detail with reference to the accompanying drawings. Further, like reference numerals will be used for like or corresponding parts throughout the drawings.

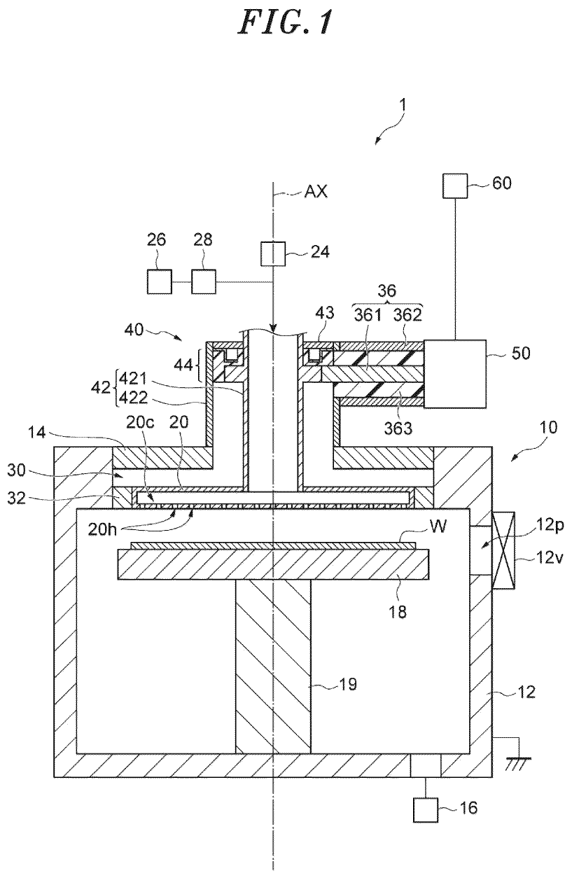

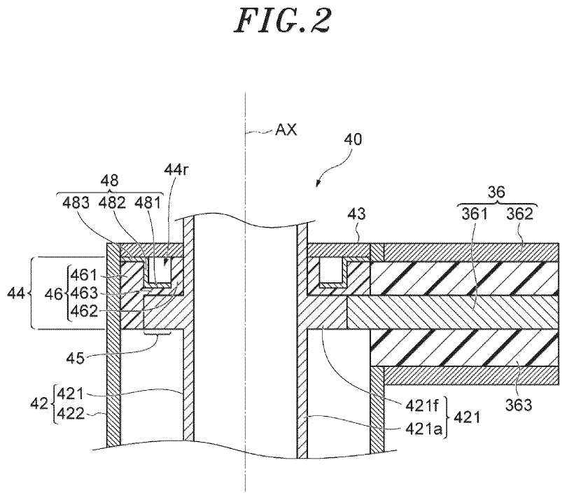

FIG. 1 is a cross-sectional view schematically showing a plasma processing apparatus according to one embodiment. FIG. 2 is a partially enlarged cross-sectional view of a waveguide of a plasma processing apparatus according to one embodiment. In a plasma processing apparatus 1 shown in FIGS. 1 and 2, a high-frequency power generated by a high-frequency power supply 60 is used for producing plasma in a chamber 10. The high-frequency power can propagate as electromagnetic waves from the high-frequency power supply 60 and be introduced into the chamber 10. The high-frequency power and the electromagnetic waves have a frequency higher than or equal to a VHF wave band. The high-frequency power and the electromagnetic waves may be VHF waves or UHF waves. The band of the VHF waves is 30 MHz to 300 MHz, and the band of the UHF waves is 300 MHz to 3 GHz.

The plasma processing apparatus 1 includes the chamber 10. The chamber 10 defines an internal space. A substrate W is processed in the internal space of the chamber 10. The chamber 10 has an axis AX as the central axis thereof. The axis AX is an axis extending in a vertical direction.

In one embodiment, the chamber 10 may include a chamber body 12. The chamber body 12 has a substantially cylindrical shape, and has an upper opening. The chamber body 12 provides a sidewall and a bottom portion of the chamber 10. The chamber body 12 is made of a metal such as aluminum. The chamber body 12 is grounded.

The sidewall of the chamber body 12 provides a passage 12p. The substrate W is transferred between the inside and the outside of the chamber 10 through the passage 12p. The passage 12p can be opened and closed by a gate valve 12v. The gate valve 12v is disposed along the sidewall of the chamber body 12.

The chamber 10 may further include an upper wall 14. The upper wall 14 is made of a metal such as aluminum. The upper wall 14 closes the upper opening of the chamber body 12 together with a coaxial waveguide 42 to be described later. The upper wall 14 is grounded together with the chamber body 12.

The bottom portion of the chamber 10 provides an exhaust port. The exhaust port is connected to an exhaust device 16. The exhaust device 16 includes a pressure controller such as an automatic pressure control valve and a vacuum pump such as a turbo molecular pump.

The plasma processing apparatus 1 may further include a substrate support 18. The substrate support 18 is disposed in the chamber 10. The substrate support 18 is configured to support a substrate W placed thereon. The substrate W is placed on the substrate support 18 in a substantially horizontal state. The substrate support 18 may be supported by a support member 19. The support member 19 extends upward from the bottom portion of the chamber 10. The substrate support 18 and the support member 19 may be made of a dielectric material such as aluminum nitride or the like.

The plasma processing apparatus 1 may further include a shower head 20. The shower head 20 is made of a metal such as aluminum. The shower head 20 has a substantially disc shape, and may have a hollow structure. The shower head 20 shares the axis AX as the central axis thereof. The shower head 20 is disposed above the substrate support 18 and below the upper wall 14. The shower head 20 constitutes a ceiling portion that defines the internal space of the chamber 10.

The shower head 20 provides a plurality of gas holes 20h. The plurality of gas holes 20h are opened toward the internal space of the chamber 10. The shower head 20 further provides a gas diffusion space 20c therein. The plurality of gas holes 20h are connected to the gas diffusion space 20c, and extend downward from the gas diffusion space 20c.

The plasma processing apparatus 1 may include, as a gas supply line, an inner conductor 421 (to be described later) of the coaxial waveguide 42. The inner conductor 421 is configured as a cylindrical line. The inner conductor 421 is made of a metal such as aluminum. The inner conductor 421 extends vertically above the shower head 20. The inner conductor 421 shares the axis AX as the central axis thereof. The lower end of the inner conductor 421 is connected to the upper center of the shower head 20. The upper center of the shower head 20 provides an inlet for a gas. The inlet is connected to the gas diffusion space 20c. The inner conductor 421 supplies a gas to the shower head 20. The gas from the inner conductor 421 is introduced into the chamber 10 from the plurality of gas holes 20h via the inlet of the shower head 20 and the gas diffusion space 20c.

In one embodiment, the plasma processing apparatus 1 may further include a first gas source 24, a second gas source 26, and a remote plasma source 28. The first gas source 24 is connected to the inner conductor 421 (i.e., the gas supply line). The first gas source 24 may be a gas source of a film forming gas. The film forming gas may include a silicon-containing gas. The silicon-containing gas may include, e.g., SiH₄. The film forming gas may further include other gases. For example, the film forming gas may further include NH₃ gas, N₂ gas, a rare gas such as Ar, and the like. The gas (e.g., the film forming gas) from the first gas source 24 is introduced into the chamber 10 from the shower head 20 via the inner conductor 421 (i.e., the gas supply line).

The second gas source 26 is connected to the inner conductor 421 (i.e., the gas supply line) via the remote plasma source 28. The second gas source 26 may be a gas source of a cleaning gas. The cleaning gas may include a halogen-containing gas. The halogen-containing gas may include, e.g., NF₃ and/or Cl₂. The cleaning gas may further include other gases. The cleaning gas may further include a rare gas such as Ar.

The remote plasma source 28 excites the gas from the second gas source 26 at a location separated from the chamber 10, thereby producing plasma. In one embodiment, the remote plasma source 28 produces plasma from the cleaning gas. The remote plasma source 28 may be any type of plasma source. The remote plasma source 28 may be, e.g., a plasma source, an inductively coupled plasma source, or a plasma source that produces plasma by microwaves. Radicals in the plasma produced in the remote plasma source 28 are introduced into the chamber 10 from the showerhead 20 via the inner conductor 421.

In order to suppress deactivation of the radicals, the inner conductor 421 (i.e., the gas supply line) may have a relatively large diameter. The outer diameter (diameter) of the inner conductor 421 is, e.g., 40 mm or more. In one example, the outer diameter (diameter) of the inner conductor 421 is 80 mm. The inner conductor 421 has a cylindrical shape, and the outer diameter (diameter) of the inner conductor 421 is the outer diameter of the inner conductor 421 at another part 421a of a flange 421f to be described later. The flange 421f constitutes a part of the inner conductor 421 in a longitudinal direction. The flange 421f has an annular shape, and extends about the axis AX. The flange 421f protrudes in a radial direction from another part 421a of the inner conductor 421. The inner conductor 421 can constitute a part of the waveguide 40 to be described later.

The shower head 20 is separated downward from the upper wall 14. The space between the shower head 20 and the upper wall 14 constitutes a part of the waveguide 30. The waveguide 30 also includes a space between the inner conductor 421 and the upper wall 14, which is provided by the inner conductor 421.

The plasma processing apparatus 1 may further include an introducing part 32. The introducing part 32 is made of a dielectric material such as aluminum oxide. The introducing part 32 is disposed along the outer periphery of the shower head 20 to introduce electromagnetic waves into the chamber 10. The introducing part 32 has an annular shape. The introducing part 32 closes the gap between the shower head 20 and the chamber body 12, and is connected to the waveguide 30. The introducing part 32 may be disposed along the sidewall of the chamber 10.

The plasma processing apparatus 1 may further include the waveguide 40. The waveguide 40 is configured to propagate electromagnetic waves to produce plasma in the chamber 10. The waveguide 40 may be disposed above the chamber 10.

The plasma processing apparatus 1 may further include a supply path 36 for electromagnetic waves. The supply path 36 is connected to the waveguide 40. In one embodiment, the supply path 36 has a coaxial structure. In other words, the supply path 36 includes a central conductor 361 and an outer conductor 362. The outer conductor 362 has a substantially cylindrical shape. The outer conductor 362 is connected to the outer conductor 422 of the coaxial waveguide 42. The central conductor 361 has a rod shape, is disposed in the outer conductor 362 to be coaxial with the outer conductor 362. The supply path 36 may further include a dielectric member 363. The dielectric member 363 fills the gap between the central conductor 361 and the outer conductor 362. The dielectric member 363 is made of, e.g., polytetrafluoroethylene (PTFE).

The central conductor 361 is connected to the inner conductor 421. Specifically, one end of the central conductor 361 is connected to the flange 421f. The flange 421f may be a part of the central conductor 361. Alternatively, the flange 421f may include the inner conductor 421 and the central conductor 361.

The plasma processing apparatus 1 further includes a high-frequency power supply 60. The other end of the central conductor 361 is connected to the high-frequency power supply 60. The high-frequency power supply 60 is configured to generate a high-frequency power as described above. The high-frequency power supply 60 will be described in detail later.

The plasma processing apparatus 1 may further include a matching device 50. In this case, the other end of the central conductor 361 is connected to the high-frequency power supply 60 via the matching device 50. The matching device 50 has an impedance matching circuit. The impedance matching circuit is configured to match an impedance of a load of the high-frequency power supply 60 to an output impedance of the high-frequency power supply 60. The impedance matching circuit has a variable impedance. The impedance matching circuit may be, e.g., a π-type circuit. The plasma processing apparatus 1 may not include the matching device 50. In this case, the other end of the central conductor 361 can be directly connected to the high-frequency power supply 60. The impedance of the load of the high-frequency power supply 60 is matched to the output impedance of the high-frequency power supply 60 by changing the frequency outputted from the high-frequency power supply 60.

In the plasma processing apparatus 1, the electromagnetic waves from the high-frequency power supply 60 are introduced into the chamber 10 from the introducing part 32 via the matching device 50, the supply path 36 (the central conductor 361), the waveguide 40, and the waveguide 30 around the shower head 20. The gas (e.g., the film forming gas) from the first gas source 24 is excited by the electromagnetic waves in the chamber 10, so that plasma is produced.

The waveguide 40 includes a resonator 44. The waveguide 40 may further include a coaxial waveguide 42 and a lid 43. In one embodiment, the coaxial waveguide 42 extends vertically above the chamber 10, and has the axis AX as the central axis thereof. The coaxial waveguide 42 includes the inner conductor 421 and the outer conductor 422 described above. The outer conductor 422 is made of a metal such as aluminum, and has a substantially cylindrical shape. The inner conductor 421 is disposed in the outer conductor 422 to be coaxial with the outer conductor 422.

The lid 43 is made of a metal such as aluminum, and closes an opening between the inner conductor 421 and the outer conductor 422 at one end (e.g., the upper end) of the coaxial waveguide 42. The lid 43 is electrically connected to the outer conductor 422. The other end (e.g., the lower end) of the outer conductor 422 is connected to the upper wall 14.

The resonator 44 is configured to resonate the electromagnetic waves therein. The resonator 44 may have a narrow half-width of 20 MHz or less as the half-width of the resonance spectrum. Further, the half-width of the resonance spectrum is the half-width of the frequency with respect to the peak in the frequency spectrum of the reflection coefficient of the high-frequency power or the electromagnetic waves. Due to the narrow half-width of the resonance spectrum, the resonator 44 may have a compact structure.

In one embodiment, the resonator 44 may have a folded waveguide for a compact size. The resonator 44 may include a plurality of portions having different impedances.

The resonator 44 may include a dielectric member 46. The resonator 44 may further include a microstrip 45. The resonator 44 may be disposed between one end (e.g., the upper end) and the other end (e.g., the lower end) of the coaxial waveguide 42. In other words, the microstrip 45 and the dielectric member 46 may be disposed between one end (e.g., the upper end) and the other end (e.g., the lower end) of the coaxial waveguide 42. In one embodiment, the resonator 44 is disposed above the bottom surface of the flange 421f.

The dielectric member 46 is made of, e.g., polytetrafluoroethylene (PTFE). The dielectric member 46 is configured to provide a plurality of portions having different impedances to the resonator 44. The dielectric member 46 includes a dielectric layer 463 as a part thereof. The dielectric layer 463 constitutes the microstrip 45. In this manner, in the plasma processing apparatus 1, a part of the dielectric member 46 constitutes the dielectric layer 463 of the microstrip. Another part of the dielectric member 46 also constitutes the resonator 44. Therefore, the resonator 44 includes a plurality of portions having different impedances. In the plasma processing apparatus 1, even the resonator 44 having a compact size can resonate electromagnetic waves, due to the microstrip 45 and the dielectric member 46.

In one embodiment, the resonator 44 may further include a ground conductor 48 in addition to the dielectric member 46. The ground conductor 48 may be disposed on the dielectric member 46. The ground conductor 48 is electrically connected to the lid 43.

The microstrip 45 of the resonator 44 may include a microstrip conductor, a dielectric layer 463, and an annular ground portion 481. The microstrip conductor of the microstrip 45 is the flange 421f described above. The dielectric layer 463 has an annular shape, and extends about the axis AX. The dielectric layer 463 is disposed on the microstrip conductor, i.e., the flange 421f. The annular ground portion 481 is a part of the ground conductor 48. The annular ground portion 481 has an annular shape, and extends about the axis AX. The annular ground portion 481 is disposed on the dielectric layer 463.

In one embodiment, the dielectric member 46 may further include a first cylindrical portion 461 and a second cylindrical portion 462. The first cylindrical portion 461 has a substantially cylindrical shape. The first cylindrical portion 461 is interposed between the outer edge of the flange 421f and the outer conductor 422, and extends toward one end (e.g., the upper end) of the coaxial waveguide 42. The central axis of the first cylindrical portion 461 may be the axis AX.

The second cylindrical portion 462 has a substantially cylindrical shape. The second cylindrical portion 462 is disposed inside the first cylindrical portion 461, and extends from the flange 421f along the inner conductor 421 toward one end (e.g., the upper end) of the coaxial waveguide 42. The central axis of the second cylindrical portion 462 may be the axis AX.

The dielectric layer 463 extends between the first cylindrical portion 461 and the second cylindrical portion 462. The dielectric layer 463 may extend between the intermediate position in the longitudinal direction (height direction) of the first cylindrical portion 461 and the lower end of the second cylindrical portion 462.

In one embodiment, the dielectric member 46 may provide a recess 44r. The recess 44r is a cavity, and extends on the dielectric layer 463 and between the first cylindrical portion 461 and the second cylindrical portion 462. The recess 44r has an annular shape, and extends about the axis AX.

The above-described ground conductor 48 may further include a cylindrical ground portion 482. The cylindrical ground portion 482 has a substantially cylindrical shape, and extends about the axis AX. The cylindrical ground portion 482 extends from the outer edge of the annular ground portion 481 toward one end (e.g., the upper end) of the coaxial waveguide 42 along the first cylindrical portion 461.

The ground conductor 48 may further include another annular ground portion 483. The annular ground portion 483 has an annular shape, and extends about the axis AX. The annular ground portion 483 extends radially outward from one end (e.g., the upper end) of the cylindrical ground portion 482. The ground conductor 48 may be electrically connected to the lid 43 by embedding the annular ground portion 483 between the lid 43 and the first cylindrical portion 461 of the dielectric member 46.

In one embodiment, the dielectric member 46 can provide different impedances in the first cylindrical portion 461, the microstrip 45, the second cylindrical portion 462, and the recess 44r. Therefore, due to the microstrip 45 and the dielectric member 46, even the resonator 44 with a considerable compact size can resonate the electromagnetic waves.

Further, the intensity of the electric field of the electromagnetic waves propagating from the microstrip 45 toward the recess 44r becomes high in a region along the inner conductor 421. Since, however, the second cylindrical portion 462 is provided in the region, abnormal discharge in the region is suppressed.

Further, in the plasma processing apparatus 1, the inner conductor 421 is connected to the upper center of the shower head 20, and the central conductor 361 of the supply path 36 for electromagnetic waves is connected to the flange 421f of the inner conductor 421. Therefore, the electromagnetic waves propagate uniformly around the inner conductor 421. The electromagnetic waves are introduced into the chamber 10 from the introducing part 32 disposed along the outer periphery of the shower head 20 via the inner conductor 421 and the shower head 20. Hence, in accordance with the plasma processing apparatus 1, it is possible to improve the uniformity of the distribution of the plasma density in the chamber 10.

Further, in accordance with the plasma processing apparatus 1, deposits formed in the chamber 10 by film formation can be removed by radicals from the plasma of the cleaning gas. The radicals from the plasma of the cleaning gas are supplied through the inner conductor 421 and the shower head 20, which serve as gas supply lines, so that the deactivation of the radicals is suppressed. Further, the radicals are uniformly supplied into the chamber 10. Accordingly, in the plasma processing apparatus 1, the cleaning of the chamber 10 can be performed uniformly and efficiently.

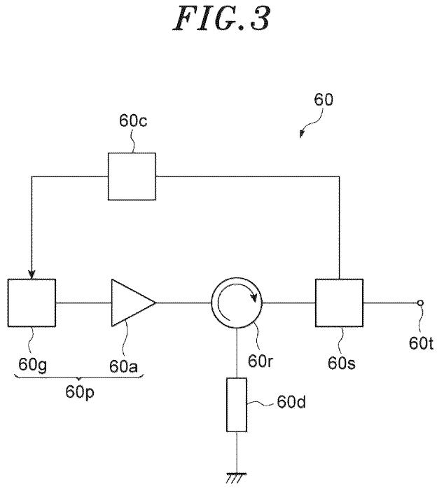

Hereinafter, the high-frequency power supply 60 will be described in detail with reference to FIG. 3. FIG. 3 schematically shows a high-frequency power supply according to one embodiment. As shown in FIG. 3, the high-frequency power supply 60 includes a power generator 60p, an output part 60t, a sensor 60s, and a controller 60c.

The power generator 60p is configured to generate a high-frequency power having a variable frequency. The frequency of the high-frequency power generated by the power generator 60p is assigned by the controller 60c. The output of the power generator 60p is connected to the output part 60t of the high-frequency power supply 60. The high-frequency power generated by the power generator 60p is outputted from the output part 60t.

In one embodiment, the power generator 60p may include an oscillator 60g and an amplifier 60a. The oscillator 60g generates a high-frequency signal having a variable frequency. The frequency of the high-frequency signal generated by the oscillator 60g is assigned by the controller 60c. The output of the oscillator 60g is connected to the input of the amplifier 60a. The amplifier 60a amplifies the high-frequency signal from the oscillator 60g, thereby generating a high-frequency power.

In one embodiment, the power generator 60p may be connected to the output part 60t via a circulator 60r. The power generator 60p is connected to a first port of the circulator 60r. A second port of the circulator 60r is connected to the output part 60t. A third port of the circulator 60r is connected to a dummy load 60d. The circulator 60r outputs the high-frequency power inputted to the first port to the output part 60t via the second port. The circulator 60r outputs the high-frequency power (reflected waves) traveling from the output part 60t to the second port to the dummy load 60d.

The sensor 60s is configured to specify the reflection coefficient of the high-frequency power for the load connected to the output part 60t. The sensor 60s may be a V-I sensor that measures a voltage and a current and specifies the reflection coefficient from the measured voltage and current. Alternatively, the sensor 60s may measure the power level of the reflected waves returned to the output part 60t, and specify the reflection coefficient from the ratio of the power level of the reflected waves to the power level of the traveling waves of the high-frequency power or the set power level of the high-frequency power.

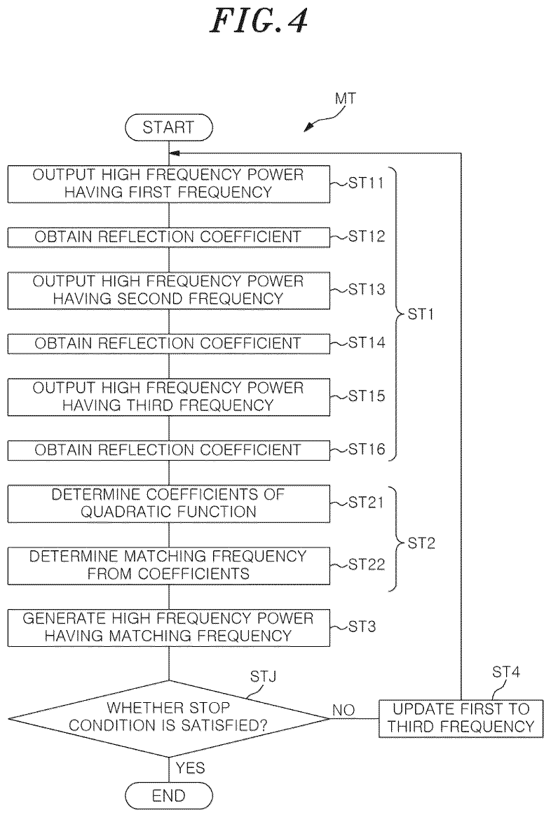

The controller 60c is configured to determine a matching frequency of the high-frequency power for the load connected to the output part 60t. The controller 60c may include a microprocessor. Hereinafter, the process of determining the matching frequency by the controller 60c and a matching method according to one embodiment will be described with reference to FIG. 4 together with FIG. 3. FIG. 4 is a flowchart of the matching method according to one embodiment.

The matching method (hereinafter referred to as “method MT”) shown in FIG. 4 is performed to determine a matching frequency that suppresses the reflection of the high-frequency power from the load. In step ST1 of the method MT, first to third frequencies different from each other are used as frequencies of the high-frequency power generated by the power generator 60p, and three reflection coefficients corresponding to the first to third frequencies are obtained from the sensor 60s by the controller 60c.

The first to third frequencies are predetermined so that the matching frequency can be detected in the frequency range between the first frequency and the third frequency. In one embodiment, the second frequency is the center frequency between the first frequency and the third frequency. The absolute value of the difference between the first frequency and the second frequency and the absolute value of the difference between the second frequency and the third frequency may be 20 MHz or less.

Step ST1 may include steps ST11 to ST16. In the step ST11, a high-frequency power having a first frequency f₁ is outputted from the high-frequency power supply 60. The first frequency f₁ is assigned to the power generator 60p by the controller 60c. In the subsequent step ST12, the reflection coefficient from the load for the high-frequency power having the first frequency f₁ is obtained from the sensor 60s by the controller 60c.

In step ST13, a high-frequency power having a second frequency f₂ is outputted from the high-frequency power supply 60. The second frequency f₂ is assigned to the power generator 60p by the controller 60c. In the subsequent step ST14, the reflection coefficient from the load for the high-frequency power having the second frequency f₂ is obtained from the sensor 60s by the controller 60c.

In step ST15, a high-frequency power having a third frequency f₃ is outputted from the high-frequency power supply 60. The third frequency f₃ is assigned to the power generator 60p by the controller 60c. In the subsequent step ST16, the reflection coefficient from the load for the high-frequency power having the third frequency f₃ is obtained from the sensor 60s by the controller 60c.

In the method MT, next, step ST2 is performed. In step ST2, the frequency of the minimum point of the quadratic function expressing the relationship between the first to third frequencies and the three reflection coefficients is determined as the matching frequency by the controller 60c.

Step ST2 may include steps ST21 and ST22. In step ST21, the coefficients of the quadratic function are determined by the controller 60c. The quadratic function expressing a reflection coefficient Γ is expressed by the following Eq. (1).

$$Γ ( f ) = {af}^{2} + bf + c \qquad Eq . ( 1 )$$

In Eq. (1), f indicates the frequency of the high-frequency power, and a, b, and c indicate the coefficients of the quadratic function.

In step ST22, the matching frequency is determined from the coefficients a, b, and c by the controller 60c. The matching frequency is determined by the following Eq. (2).

$${f}_{min} = - \frac{b}{2 a} \qquad Eq . ( 2 )$$

In Eq. (2), fₘᵢₙ indicates the matching frequency.

In one embodiment, the coefficients a, b, and c can be obtained by the following Eq. (3).

$$( \begin{matrix}a \\ b \\ c\end{matrix} ) = {( \begin{matrix}{f}_{1}^{2} & {f}_{1} & 1 \\ {f}_{2}^{2} & {f}_{2} & 1 \\ {f}_{3}^{2} & {f}_{3} & 1\end{matrix} )}^{- 1} ( \begin{matrix}{Γ}_{1} \\ {Γ}_{2} \\ {Γ}_{3}\end{matrix} ) \qquad Eq . ( 3 )$$

In Eq. (3), f₁ indicates the first frequency, f₂ indicates the second frequency, and f₃ indicates the third frequency. Γ₁ indicates the reflection coefficient of the high-frequency power having the first frequency, Γ₂ indicates the reflection coefficient of the high-frequency power having the second frequency, and Γ₃ indicates the reflection coefficient of the high-frequency power having the third frequency.

In the method MT, next, step ST3 is performed. In step ST3, the power generator 60p is controlled by the controller 60c to generate the high-frequency power having the matching frequency determined in step ST2.

In one embodiment, the matching frequency may be updated. In this case, in step STJ, it is determined whether the stop condition is satisfied. The stop condition is satisfied when the number of updates of the matching frequency has reached a predetermined number. The predetermined number is one or more. If the stop condition is satisfied, the method MT is ended. On the other hand, if the stop condition is not satisfied, the processing proceeds to step ST4.

In step ST4, the first to third frequencies are updated by the controller 60c. Specifically, the current matching frequency is used as the second frequency. Further, the first and third frequencies are set with the second frequency as the center frequency. Further, the absolute value of the difference between the first frequency and the second frequency and the absolute value of the difference between the second frequency and the third frequency may be reduced from the absolute value of the difference between the first frequency and the second frequency and the absolute value of the difference between the second frequency and the third frequency before step ST4, respectively. For example, the absolute value of the difference between the first frequency and the second frequency and the absolute value of the difference between the second frequency and the third frequency may be set to 5 MHz or less. After step ST4, steps ST1 to ST3 are repeated again.

As described above, the matching frequency of the high-frequency power outputted by the high-frequency power supply 60 is determined from the coefficients of the quadratic function that specifies the relationship between the three frequencies and the three reflection coefficients. Therefore, the matching frequency is quickly determined. In one embodiment, steps ST1 to ST3 are repeated to update the matching frequency. Therefore, it is possible to further reduce the reflection of the high-frequency power from the load.

While various embodiments have been described above, the present disclosure is not limited to the above-described embodiments, and various additions, omissions, substitutions and changes may be made. Further, other embodiments can be implemented by combining elements in different embodiments.

For example, the matching frequency may be determined by a controller other than the controller 60c that is provided outside the high-frequency power supply 60. Further, the sensor 60s may not be a part of the high-frequency power supply 60, and may be provided outside the high-frequency power supply 60. Further, the plasma processing apparatus including the resonator having the above-described resonance spectrum may be a plasma processing apparatus having a structure different from that of the plasma processing apparatus 1.

Here, various exemplary embodiments included in the present disclosure will be described in the following [E1] to [E20].

### [E1]

A high-frequency power supply comprising:
a power generator configured to generate a high-frequency power having a variable frequency;
an output part configured to output the high-frequency power;
a sensor configured to specify a reflection coefficient of the high-frequency power for a load connected to the output part; and
a controller configured to determine a matching frequency of the high-frequency power for the load,
wherein the controller is configured to:
(i) obtain three reflection coefficients corresponding to a first frequency, a second frequency, and a third frequency from the sensor by using the first frequency, the second frequency, and the third frequency that are different from each other as frequencies of the high-frequency power;
(ii) determine, as the matching frequency, a frequency of a minimum point of a quadratic function that expresses the relationship between the first to third frequencies and the three reflection coefficients; and
(iii) control the power generator to generate the high-frequency power having the matching frequency.

### [E2]

The high-frequency power supply of E1, wherein the quadratic function is expressed by the following Eq. (1),

$$Γ ( f ) = {af}^{2} + bf + c \qquad Eq . ( 1 )$$

wherein Γ is a reflection coefficient, f is a frequency of the high-frequency power, and a, b, and c are coefficients, and
the controller is configured to determine the matching frequency by the following Eq. (2),

$${f}_{min} = - \frac{b}{2 a} \qquad Eq . ( 2 )$$

wherein fₘᵢₙ is the matching frequency.

### [E3]

The high-frequency power supply of E2, wherein the controller is configured to determine the a, the b, and the c by the following Eq. (3),

$$( \begin{matrix}a \\ b \\ c\end{matrix} ) = {( \begin{matrix}{f}_{1}^{2} & {f}_{1} & 1 \\ {f}_{2}^{2} & {f}_{2} & 1 \\ {f}_{3}^{2} & {f}_{3} & 1\end{matrix} )}^{- 1} ( \begin{matrix}{Γ}_{1} \\ {Γ}_{2} \\ {Γ}_{3}\end{matrix} ) \qquad Eq . ( 3 )$$

wherein f₁ is the first frequency, f₂ is the second frequency, f₃ is the third frequency, Γ₁ is a reflection coefficient of the high-frequency power having the first frequency, Γ₂ is a reflection coefficient of the high-frequency power having the second frequency, and Γ₃ is a reflection coefficient of the high-frequency power having the third frequency.

### [E4]

The high-frequency power supply of any one of E1 to E3, wherein the second frequency is a center frequency between the first frequency and the third frequency.

### [E5]

The high-frequency power supply of E4, wherein an absolute value of a difference between the first frequency and the second frequency and an absolute value of a difference between the second frequency and the third frequency are 20 MHz or less.

### [E6]

The high-frequency power supply of E4 or E5, wherein the controller is configured to further execute the (i), the (ii), and the (iii) by using the matching frequency as the second frequency and by reducing the absolute value of the difference between the first frequency and the second frequency and the absolute value of the difference between the second frequency and the third frequency.

### [E7]

The high-frequency power supply of E6, wherein in further executing the (i), the (ii), and the (iii), the absolute value of the difference between the first frequency and the second frequency and the absolute value of the difference between the second frequency and the third frequency are 5 MHz or less.

### [E8]

The high-frequency power supply of any one of E1 to E7, wherein the high-frequency power has a frequency higher than or equal to a frequency in a VHF waveband.

### [E9]

A plasma processing apparatus comprising:
a chamber;
a high-frequency power supply configured to generate a high-frequency power having a variable frequency to produce plasma in the chamber;
a sensor configured to specify a reflection coefficient of the high-frequency power for a load connected to the high-frequency power supply; and
a controller configured to determine a matching frequency of the high-frequency power for the load,
wherein the controller is configured to:
(i) obtain three reflection coefficients corresponding to a first frequency, a second frequency, and a third frequency from the sensor by using the first frequency, the second frequency, and the third frequency that are different from each other as frequencies of the high-frequency power;
(ii) determine, as the matching frequency, a frequency of a minimum point of a quadratic function that expresses the relationship between the first to third frequencies and the three reflection coefficients; and
(iii) control the high-frequency power supply to generate the high-frequency power having the matching frequency.

### [E10]

The plasma processing apparatus of E9, wherein the quadratic function is expressed by the following Eq. (1),

$$Γ ( f ) = a {f}^{2} + b f + c \qquad Eq . ( 1 )$$

wherein Γ is a reflection coefficient, f is a frequency of the high-frequency power, and a, b, and c are coefficients, and
the controller is configured to determine the matching frequency by the following Eq. (2),

$${f}_{min} = - \frac{b}{2 a} \qquad Eq . ( 2 )$$

wherein fₘᵢₙ is the matching frequency.

### [E11]

The plasma processing apparatus of E10, wherein the controller is configured to determine the a, the b, and the c by the following Eq. (3), and

$$( \begin{matrix}a \\ b \\ c\end{matrix} ) = {( \begin{matrix}{f}_{1}^{2} & {f}_{1} & 1 \\ {f}_{2}^{2} & {f}_{2} & 1 \\ {f}_{3}^{2} & {f}_{3} & 1\end{matrix} )}^{- 1} ( \begin{matrix}{Γ}_{1} \\ {Γ}_{2} \\ {Γ}_{3}\end{matrix} ) \qquad Eq . ( 3 )$$

in Eq. (3), f₁ is the first frequency, f₂ is the second frequency, f₃ is the third frequency, Γ₁ is the reflection coefficient of the high-frequency power having the first frequency, Γ₂ is the reflection coefficient of the high-frequency power having the second frequency, and Γ₃ is the reflection coefficient of the high-frequency power having the third frequency.

### [E12]

The plasma processing apparatus of any one of E9 to E11, wherein the second frequency is a center frequency between the first frequency and the third frequency.

### [E13]

The plasma processing apparatus of E12, wherein the controller is configured to further execute the (i), the (ii), and the (iii) by using the matching frequency as the second frequency and by reducing the absolute value of the difference between the first frequency and the second frequency and the absolute value of the difference between the second frequency and the third frequency.

### [E14]

The plasma processing apparatus of any one of E9 to E13, wherein the high-frequency power has a frequency higher than or equal to a frequency in a VHF waveband.

### [E15]

The plasma processing apparatus of any one of E9 to E14, further comprising:
a waveguide connected between the high-frequency power supply and the chamber, through which the high-frequency power propagates as electromagnetic waves, including a resonator configured to resonate the electromagnetic waves therein,
wherein the resonator includes a dielectric member that provides a plurality of portions having different impedances in the resonator.

### [E16]

The plasma processing apparatus of E15, wherein the resonator further includes a microstrip, and
a part of the dielectric member constitutes a dielectric layer of the microstrip.

### [E17]

The plasma processing apparatus of E15 or E16, wherein the dielectric member provides a recess that is a cavity through which the electromagnetic waves propagate.

### [E18]

The plasma processing apparatus of any one of E15 to E17, wherein a half-width of a resonant spectrum of the resonator is 20 MHz or less.

### [E19]

A matching method comprising:
(i) obtaining three reflection coefficients corresponding to a first frequency, a second frequency, and a third frequency from a sensor by using the first frequency, the second frequency, and the third frequency that are different from each other as frequencies of a high-frequency power generated by a high-frequency power supply;
(ii) determining a frequency of a minimum point of a quadratic function that specifies the relationship between the first to third frequencies and the three reflection coefficients, as a matching frequency of the high-frequency power for a load of the high-frequency power supply;
(iii) generating the high-frequency power having the matching frequency by the high-frequency power supply.

### [E20]

The matching method of E19, wherein the quadratic function is expressed by the following Eq. (1),

$$Γ ( f ) = a {f}^{2} + b f + c \qquad Eq . ( 1 )$$

wherein Γ is a reflection coefficient, f is a frequency of the high-frequency power, and a, b, and c are coefficients, and
the matching frequency is determined by the following Eq. (2),

$${f}_{min} = - \frac{b}{2 a} \qquad Eq . ( 2 )$$

wherein fₘᵢₙ is the matching frequency.

From the above description, it will be appreciated that various embodiments of the present disclosure have been described herein for purposes of illustration, and that various changes can be made without departing from the scope and spirit of the present disclosure. Therefore, the various embodiments disclosed herein are not intended to be limiting, with a true scope and spirit being indicated by the appended claims.

1. A high-frequency power supply comprising:
a power generator configured to generate a high-frequency power having a variable frequency;
an output part configured to output the high-frequency power;
a sensor configured to specify a reflection coefficient of the high-frequency power for a load connected to the output part; and
a controller configured to determine a matching frequency of the high-frequency power for the load,
wherein the controller is configured to:
(i) obtain three reflection coefficients corresponding to a first frequency, a second frequency, and a third frequency from the sensor by using the first frequency, the second frequency, and the third frequency that are different from each other as frequencies of the high-frequency power;
(ii) determine, as the matching frequency, a frequency of a minimum point of a quadratic function that expresses the relationship between the first to third frequencies and the three reflection coefficients; and
(iii) control the power generator to generate the high-frequency power having the matching frequency.

2. The high-frequency power supply of claim 1, wherein the quadratic function is expressed by the following Eq. (1),
$$Γ ( f ) = a {f}^{2} + b f + c \qquad Eq . ( 1 )$$
wherein Γ is a reflection coefficient, f is a frequency of the high-frequency power, and a, b, and c are coefficients, and
the controller is configured to determine the matching frequency by the following Eq. (2),
$${f}_{min} = - \frac{b}{2 a} \qquad Eq . ( 2 )$$
wherein fₘᵢₙ is the matching frequency.

3. The high-frequency power supply of claim 2, wherein the controller is configured to determine the a, the b, and the c by the following Eq. (3),
$$( \begin{matrix}a \\ b \\ c\end{matrix} ) = {( \begin{matrix}{f}_{1}^{2} & {f}_{1} & 1 \\ {f}_{2}^{2} & {f}_{2} & 1 \\ {f}_{3}^{2} & {f}_{3} & 1\end{matrix} )}^{- 1} ( \begin{matrix}{Γ}_{1} \\ {Γ}_{2} \\ {Γ}_{3}\end{matrix} ) \qquad Eq . ( 3 )$$
wherein f₁ is the first frequency, f₂ is the second frequency, f₃ is the third frequency, Γ₁ is a reflection coefficient of the high-frequency power having the first frequency, Γ₂ is a reflection coefficient of the high-frequency power having the second frequency, and Γ₃ is a reflection coefficient of the high-frequency power having the third frequency.

4. The high-frequency power supply of claim 1, wherein the second frequency is a center frequency between the first frequency and the third frequency.

5. The high-frequency power supply of claim 4, wherein an absolute value of a difference between the first frequency and the second frequency and an absolute value of a difference between the second frequency and the third frequency are 20 MHz or less.

6. The high-frequency power supply of claim 4, wherein the controller is configured to further execute the (i), the (ii), and the (iii) by using the matching frequency as the second frequency and by reducing the absolute value of the difference between the first frequency and the second frequency and the absolute value of the difference between the second frequency and the third frequency.

7. The high-frequency power supply of claim 6, wherein in further executing the (i), the (ii), and the (iii), the absolute value of the difference between the first frequency and the second frequency and the absolute value of the difference between the second frequency and the third frequency are 5 MHz or less.

8. The high-frequency power supply of claim 1, wherein the high-frequency power has a frequency higher than or equal to a frequency in a VHF waveband.

9. A plasma processing apparatus comprising:
a chamber;
a high-frequency power supply configured to generate a high-frequency power having a variable frequency to produce plasma in the chamber;
a sensor configured to specify a reflection coefficient of the high-frequency power for a load connected to the high-frequency power supply; and
a controller configured to determine a matching frequency of the high-frequency power for the load,
wherein the controller is configured to:
(i) obtain three reflection coefficients corresponding to a first frequency, a second frequency, and a third frequency from the sensor by using the first frequency, the second frequency, and the third frequency that are different from each other as frequencies of the high-frequency power;
(ii) determine, as the matching frequency, a frequency of a minimum point of a quadratic function that expresses the relationship between the first to third frequencies and the three reflection coefficients; and
(iii) control the high-frequency power supply to generate the high-frequency power having the matching frequency.

10. The plasma processing apparatus of claim 9, wherein the quadratic function is expressed by the following Eq. (1),
$$Γ ( f ) = a {f}^{2} + b f + c \qquad Eq . ( 1 )$$
wherein Γ is a reflection coefficient, f is a frequency of the high-frequency power, and a, b, and c are coefficients, and
the controller is configured to determine the matching frequency by the following Eq. (2),
$${f}_{min} = - \frac{b}{2 a} \qquad Eq . ( 2 )$$
wherein fₘᵢₙ is the matching frequency.

11. The plasma processing apparatus of claim 10, wherein the controller is configured to determine the a, the b, and the c by the following Eq. (3), and
$$( \begin{matrix}a \\ b \\ c\end{matrix} ) = {( \begin{matrix}{f}_{1}^{2} & {f}_{1} & 1 \\ {f}_{2}^{2} & {f}_{2} & 1 \\ {f}_{3}^{2} & {f}_{3} & 1\end{matrix} )}^{- 1} ( \begin{matrix}{Γ}_{1} \\ {Γ}_{2} \\ {Γ}_{3}\end{matrix} ) \qquad Eq . ( 3 )$$
in Eq. (3), f₁ is the first frequency, f₂ is the second frequency, f₃ is the third frequency, Γ₁ is the reflection coefficient of the high-frequency power having the first frequency, Γ₂ is the reflection coefficient of the high-frequency power having the second frequency, and Γ₃ is the reflection coefficient of the high-frequency power having the third frequency.

12. The plasma processing apparatus of claim 9, wherein the second frequency is a center frequency between the first frequency and the third frequency.

13. The plasma processing apparatus of claim 12, wherein the controller is configured to further execute the (i), the (ii), and the (iii) by using the matching frequency as the second frequency and by reducing the absolute value of the difference between the first frequency and the second frequency and the absolute value of the difference between the second frequency and the third frequency.

14. The plasma processing apparatus of claim 9, wherein the high-frequency power has a frequency higher than or equal to a frequency in a VHF waveband.

15. The plasma processing apparatus of claim 9, further comprising:
a waveguide connected between the high-frequency power supply and the chamber, through which the high-frequency power propagates as electromagnetic waves, including a resonator configured to resonate the electromagnetic waves therein,
wherein the resonator includes a dielectric member that provides a plurality of portions having different impedances in the resonator.

16. The plasma processing apparatus of claim 15, wherein the resonator further includes a microstrip, and
a part of the dielectric member constitutes a dielectric layer of the microstrip.

17. The plasma processing apparatus of claim 15, wherein the dielectric member provides a recess that is a cavity through which the electromagnetic waves propagate.

18. The plasma processing apparatus of claim 15, wherein a half-width of a resonant spectrum of the resonator is 20 MHz or less.

19. A matching method comprising:
(i) obtaining three reflection coefficients corresponding to a first frequency, a second frequency, and a third frequency from a sensor by using the first frequency, the second frequency, and the third frequency that are different from each other as frequencies of a high-frequency power generated by a high-frequency power supply;
(ii) determining a frequency of a minimum point of a quadratic function that specifies the relationship between the first to third frequencies and the three reflection coefficients, as a matching frequency of the high-frequency power for a load of the high-frequency power supply;
(iii) generating the high-frequency power having the matching frequency by the high-frequency power supply.

20. The matching method of claim 19, wherein the quadratic function is expressed by the following Eq. (1),
$$Γ ( f ) = a {f}^{2} + b f + c \qquad Eq . ( 1 )$$
wherein Γ is a reflection coefficient, f is a frequency of the high-frequency power, and a, b, and c are coefficients, and
the matching frequency is determined by the following Eq. (2),
$${f}_{min} = - \frac{b}{2 a} \qquad Eq . ( 2 )$$
wherein fₘᵢₙ is the matching frequency.
